(19) United States
(12) Patent Application Publication
(10) Pub. No.: US 2010/0295594 A1
(43) Pub. Date: Nov. 25, 2010

(54) Source Follower Attenuator

(76) Inventor: Tee Hui Teo, Singapore (SG)

Correspondence Address: FISH & RICHARDSON, PC, P.O. BOX 1022, MINNEAPOLIS, MN, 55440-1022, US

(21) Appl. No.: 12/516,193

(22) PCT Filed: Nov. 24, 2006
(86) PCT No.: PCT/SG06/00361

§ 371 Date: Apr. 23, 2010

(51) Int. Cl. H03L 5/00

(52) U.S. Cl. 327/308

(57) ABSTRACT

The present invention discloses a source follower attenuator circuit comprising a current source; an input transistor with a source connected to the current source and a drain connected to ground; a control transistor with a source connected to the current source and a drain connected to ground; wherein an attenuated output signal across the source and drain of the control transistor is controlled by transconductances, in an on-state, of the input transistor and of the control transistor respectively.

### FIELD OF INVENTION

The invention broadly relates to a source follower attenuator circuit, to a differential source follower attenuator, and to a method for attenuating a signal.

### BACKGROUND

An attenuator is an electronic device or circuit that reduces the amplitude or power of a signal without appreciably distorting the signal's waveform. Conventional attenuators are passive devices made from resistors. The degree of attenuation may be fixed, continuously adjustable, or incrementally adjustable.

An existing attenuator circuit utilises a switched resistive network, termed as ladder resistive network attenuator. An example of the attenuator is shown in FIG. 1 and the attenuator (100) is commonly used in discrete circuits. A resistive network based attenuator has a number of disadvantages, which includes:
1. Resistors of the switched resistive network occupy a larger silicon area with higher cost;
2. Higher power input buffer and output buffer are required to drive the attenuator and subsequent circuits. These buffers consume large amount of power; and
3. AC coupled circuit is needed which prevents the attenuator to be used in systems where DC coupling is mandatory.

These disadvantages make the resistive attenuator not suitable for integrated circuit implementation. Hence, in integrated circuits, common source based attenuators are adopted for either fixed or variable attenuators.

An existing common source based source degeneration amplifier (attenuator) is illustrated in FIG. 2. The degree of attenuation of this attenuator (200), which is given in equation 1, can be varied by changing the resistance of the load resistor R_{load}, the degeneration resistor R_{degen}, or both.

$$G = \frac{{R}_{load}}{\frac{1}{gm} + {R}_{degen}} \qquad ( 1 )$$

Here, gm is the transconductance of an input transistor and G is the attenuation degree. It can be understood from equation 1 that accuracy of attenuation of the attenuator (200) is affected by the transconductance gm. The value of gm needs to be much larger than the R_{degen} to reach acceptable linearity accuracy for R_{load} over R_{degen}, which means that large current consumption is inevitable to boost up the gm. However, even with the large current, the accuracy of attenuation cannot be improved in CMOS based circuits because room for gm improvement is very limited for CMOS based circuits. The situation becomes worse in deep submicron process CMOS, where output impedance of a transistor is small which further reduces attenuation accuracy. As a result, the circuit (200) of FIG. 2 is more commonly adopted in bipolar junction transistor (BJT) based circuits, where larger gm can be obtained easily. Therefore, there remain many problems for obtaining CMOS based attenuators, which are suitable for integrated circuits.

A need therefore exists to provide an attenuator that seeks to address at least one of the above problems.

### SUMMARY

According to a first aspect of the present invention, there is provided a source follower attenuator circuit comprising a current source; an input transistor with a source connected to the current source and a drain connected to ground; a control transistor with a source connected to the current source and a drain connected to ground; wherein an attenuated output signal across the source and drain of the control transistor is controlled by transconductances, in an on-state, of the input transistor and of the control transistor respectively.

The attenuator circuit may further comprise a RC low-pass filter circuit connected between the gate of the input transistor and the gate of the control transistor for self-biasing the control transistor from an input voltage provided at the gate of the input transistor.

The RC low-pass filter circuit may comprise MOS components.

The attenuator circuit may further comprise a plurality of control transistors, each control transistor with a source connected to the current source and a drain connected to ground and with gates of the respective control transistors are connected in series to a biasing voltage, wherein the attenuated output signal across the source and drain of one of the control transistors is controlled by transconductances, in an on-state, of the input transistor and all of the plurality of control transistors respectively.

The attenuator circuit may further comprise a plurality of control transistors, each control transistor with a source connected to the current source and a drain connected to ground and with gates of the respective control transistors are connected in parallel to a biasing voltage, wherein the attenuated output signal across the source and drain of one of the control transistors is variably controlled by the transconductance, in an on-state, of the input transistor and by transconductances of those of the plurality of control transistors which are in an on state respectively.

The attenuator circuit may further comprise switches for controlling the on state of the respective control transistors.

Each of the switches may comprise two switch elements for preventing signals from feeding through the switches.

According to a second aspect of the present invention, there is provided a differential source follower attenuator comprising a first and a second attenuator circuits as claimed in any one of claims 1 to 5; wherein the current source of the first attenuator circuit comprises a positive current source, and the current source of the second attenuator circuit comprises a negative current source.

The source of each control transistor of the first attenuator circuit may be connected to the negative current source of the second attenuator circuit, and the source of each control transistor of the second attenuator circuit is connected to the positive current source of the first attenuator circuit, for DC offset through cross-coupling of the first and second attenuator circuits.

According to a third aspect of the present invention, there is provided a method for attenuating a signal comprising providing a current source; providing an input transistor with a source connected to the current source and a drain connected to ground; providing a control transistor with a source connected to the current source and a drain connected to ground; obtaining an attenuated output signal across the source and drain of the control transistor such that the attenuating is controlled by transconductances, in an on-state, of the input transistor and of the control transistor respectively.

### BRIEF DESCRIPTION OF THE DRAWINGS

The invention will now be described with reference to the enclosed drawings, in which:

FIG. 1 shows an existing ladder formed resistive network attenuator;

FIG. 2 shows an existing common source amplifier using resistive load and degeneration for attenuation;

FIG. 3 shows a basic circuit of a Source Follower Attenuator (SFA);

FIG. 4 shows a differential SFA circuit;

FIG. 5 shows an input self-biased differential SFA circuit;

FIG. 6 shows a DC offset cancellation SFA circuit;

FIG. 7 shows a differential source follower attenuator with switches in series;

FIG. 8 shows a differential source follower attenuator with switches in parallel;

FIG. 9 shows a CMOS implemented SFA of FIG. 8 with 2 bits control switches;

FIG. 10 shows measured variable gain control of the SFA of FIG. 9; and

FIG. 11 shows a flowchart illustrating a method for attenuating a signal according to an example embodiment.

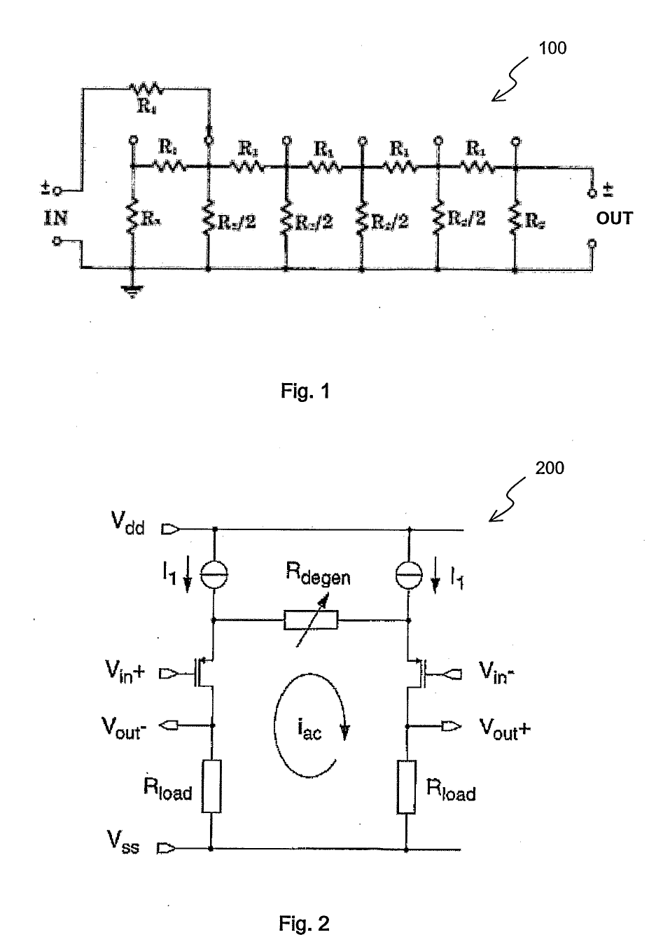

### DETAILED DESCRIPTION

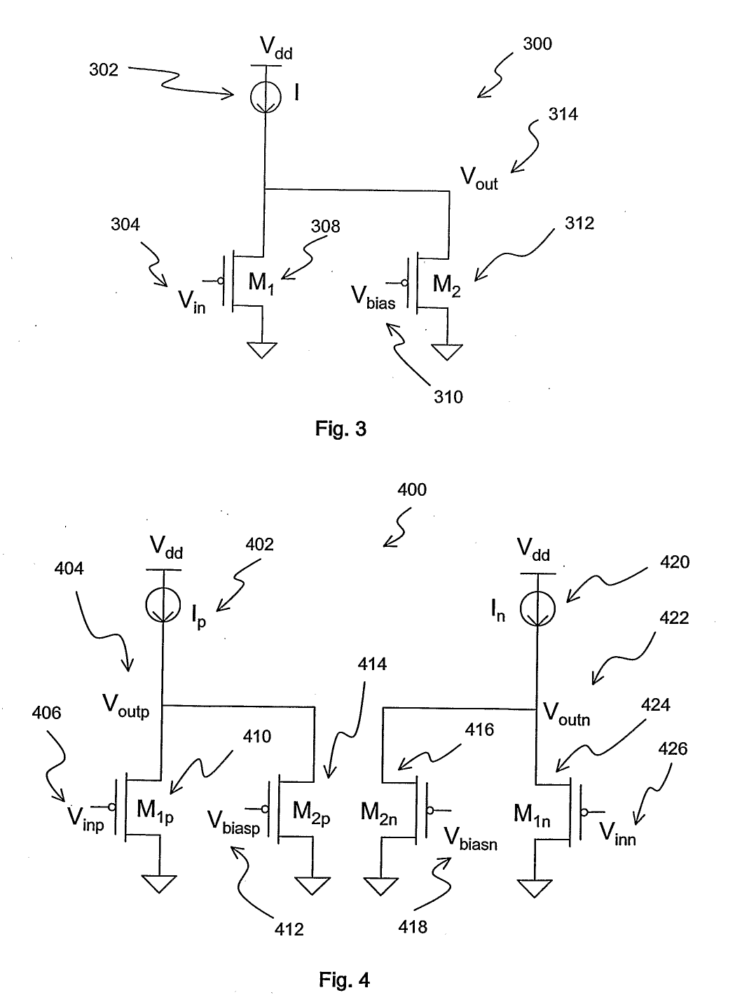

Referring to FIG. 3, a basic circuit (300) of a Source Follower Attenuator (SFA) is shown and the current source is denoted as I (302). The SFA (300) is a variable attenuator. The degree of attenuation of the SFA (300) is calculated according to equation 2 below. Here, M₂ denotes one PMOS transistor (312) primarily used to control the degree of attenuation and M₁ denotes another PMOS transistor (308) used as an input transistor. Alternatively, M₂ (312) and M₁ (308) can be termed as control transistor and input transistor respectively.

In FIG. 3, the two PMOS transistors (M₁ and M₂) (308, 312) are connected in parallel between a current source I (302) and the ground at their sources and drains. The gate of M₁ is regulated by an input voltage Vᵢₙ (304) and the gate of M₂ (308) is set by a bias voltage V_{bias} (310). A voltage output (Vₒᵤₜ)(314) is taken from the sources of M₂ (308) and M₁ (312).

The inventors have recognised that an attenuator circuit incorporating a source follower can exploit characteristics of the source follower, such as efficiently handling signals with large amplitude and providing good linearity between input and output with low power consumption, as well as operating at low voltage and provide a wide bandwidth.

In FIG. 3, assuming R is the output impedance of the current source I (302), the degree of attenuation G of the attenuator circuit (300) of FIG. 3 can be expressed as.

$$G = \frac{R + \frac{1}{{gm}_{M 2}}}{R + \frac{1}{{gm}_{M 2}} + \frac{1}{{gm}_{M 1}}} \qquad ( 2 )$$

Since R is normally much higher than 1/gm of the input device M₁ (308), the degree of attenuation can be approximated as the ratio of the transconductances (gm_{M1} and gm_{M2}) of the input transistors M₁ (308) and M₂ (312) as shown in equation 3 and further in equation 4.

$$\begin{matrix}G \approx \frac{\frac{1}{{gm}_{M 2}}}{\frac{1}{{gm}_{M 2}} + \frac{1}{{gm}_{M 1}}} & ( 3 ) \\ G = \frac{{gm}_{M 1}}{{gm}_{M 1} + {gm}_{M 2}} & ( 4 )\end{matrix}$$

Since transconductances (gm) of PMOS transistors are proportional to the aspect ratios {(W/L)_{M1} and (W/L)_{M2}} of the transistors (M₁ 308 and M₂ 312) (gm∝W/L), the degree of attenuation G can be transformed into equation 5. In equation 5, the DC voltage value of Vᵢₙ (304) and V_{bias} (310) are made to be the same. The transconductance of M₂ (gm_{M2}) can be regulated by varying V_{bias} (310), which provides another means of attenuation control, in addition to the voltage settings Vᵢₙ (304).

$$G = \frac{{( W / L )}_{M 1}}{{( W / L )}_{M 1} + {( W / L )}_{M 2}} \qquad ( 5 )$$

In most integrated circuits, differential circuits are often used. A differential circuit based SFA (400) is constructed as shown in FIG. 4. In FIG. 4, the basic circuit (300) of FIG. 3 has been mirrored to provide a positive current Iₚ (402) and a negative current Iₙ (420) separately. In other words, at the positive current Iₚ (402) side, two PMOS transistors M₁ₚ (410) and M₂ₚ (414) are connected in parallel between the current source Iₚ (402) and ground at their sources and drains. An output voltage (V_{Outp}) (404) at the positive current Iₚ (402) side is taken at the sources of transistors M₁ₚ (410) and M₂ₚ (414). The gates of M₁ₚ (410) and M₂ₚ (414) are controlled by a positive input voltage Vᵢₙₚ (406) and a positive V_{biasp} (412) respectively. Symmetrically, on the negative current Iₙ (420) side, transistors M₂ₙ (416) and M₁ₙ (424) are connected between the negative current source Iₙ (420) and ground. The negative voltage output Vₒᵤₜₙ (422) is taken from the sources of M₂ₙ (416) and M₁ₙ (424). In a like manner, a negative bias voltage V_{biasn} (418) and a negative input voltage Vᵢₙₙ (426) are provided to control the gates of M₂ₙ (416) and M₁ₙ (424) respectively.

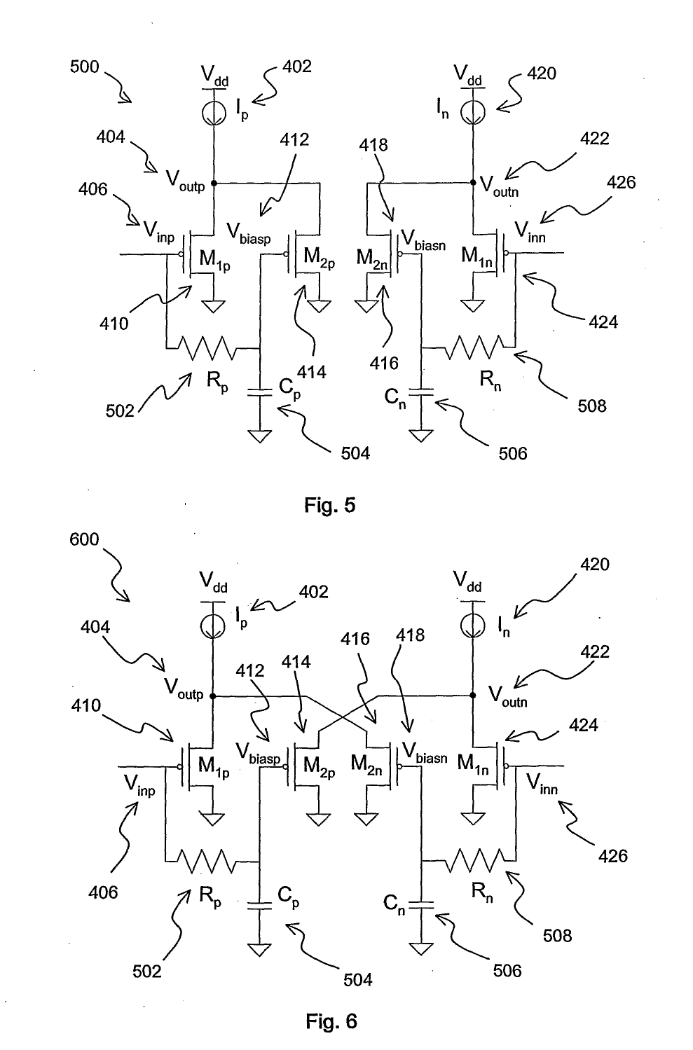

To simplify the circuit of FIG. 4 (400), a self-biased circuit (500) is introduced to provide biasing voltages V_{bias} in FIG. 5. Referring to FIG. 5, at the positive current Iₚ (402) side, DC bias is extracted from the positive input voltage Vᵢₙₚ (406) using a RC low-pass filter. As shown in FIG. 5, the gate of M₁ₚ (410) is connected to a resistor Rₚ (502) and a suitable capacitor Cₚ (504) to ground in series. The gate of M₂ₚ (414) for receiving a positive biasing voltage V_{biasp} (412) is taken between the resistor Rₚ (502) and the capacitor Cₚ (504). The output voltage at the positive current side Vₒᵤₜₚ (404) is taken from the sources of M₁ₚ (406) and M₂ₚ (412). At the negative current Iₙ (420) side, similar to the side of the positive current, the wiring is mirrored for the negative current. In other words, a capacitor Cₙ (506) and a resistor Rₙ (508) formed low pass RC filter is connected to the gate of M₁ₙ (424) and ground. V_{biasn} for M₂ₙ (416) is taken between the resistor Rₙ (508) and capacitor Cₙ (506). The negative voltage output Vₒᵤₜₙ (422) is taken from the sources of M₁ₙ (424) and M₂ₙ (416). In both the SFAs (400, 500), M₂ₚ (414) and M₂ₙ (416) are control transistors while M₁ₚ (410) and M₁ₙ (424) are input transistors.

To reduce DC-offset from inputs, a controlling transistor can be cross-coupled to cancel DC components from input signals. An example of the DC inputs cross-coupled attenuator is shown in FIG. 6. The attenuator (600) of FIG. 6 has similar topology as the SFA (500) of FIG. 5. However, the source of M₂ₙ (416) at the negative current Iₙ (402) side is cross-coupled to the positive current input Iₚ (402) to provide positive voltage output Vₒᵤₜₚ (404). On the other hand, the source of M₂ₚ (414) at the positive current Iₚ (402) side is cross-coupled to the negative current signal input Iₙ (420) to provide a negative voltage output Vₒᵤₜₙ (422).

In this implementation, it is assumed that the DC bias is provided by the attenuator (600) itself, which is common in source followers. However, this may present an issue in biasing the attenuator device (600) because V_{gs} (gate to source voltage) of the input transistors M₁ₚ M₁ₙ (410, 424) and attenuating transistors M₂ₚ M₂ₙ (414, 416) need to be the same size to make the relationship of equation 2 and 3 valid. This can be achieved if AC coupling is adopted and biasing voltages (V_{biasp}, V_{biasn}) (412, 418) of the input transistors (410, 424) can be set by a voltage biasing circuit. Further, the SFA (600) may work better if DC coupling is used with filters. In this case, two low-pass RC filters are employed as shown in FIG. 6. The RC filters extract the DC value of the incoming signals and blase the attenuating transistors (414, 416). Thus, the SFA (600) can also be DC coupled directly. The implementation of a RC filter also brings an advantage of reducing DC offset. If the SFA (600) is used in a direct conversion transceiver, a RC filter actually serves the above two purposes without compromising other performance aspects. It is noted that the self-biased circuit (600) does not consume any current.

In the above-mentioned attenuators (500, 600), resistors (Rₚ, Rₙ) (502, 508) and capacitors (Cₚ, Cₙ) (504, 506) are used which is more suitable for discrete circuits instead of integrated circuits. However, both the resistors (Rₚ, Rₙ) (502, 508) and the capacitors (Cₚ, Cₙ) (504, 506) can be replaced by MOS resistors and MOS capacitors, which is commonly known (i.e., PMOS, NMOS, CMOS configured). Here, resistors (Rₚ, Rₙ) (502, 508) and capacitors (Cₚ, Cₙ) (504, 506) are used for providing appropriate biasing voltage at the gates of attenuating transistors M₂ₚ (414) and M₂ₙ (416).

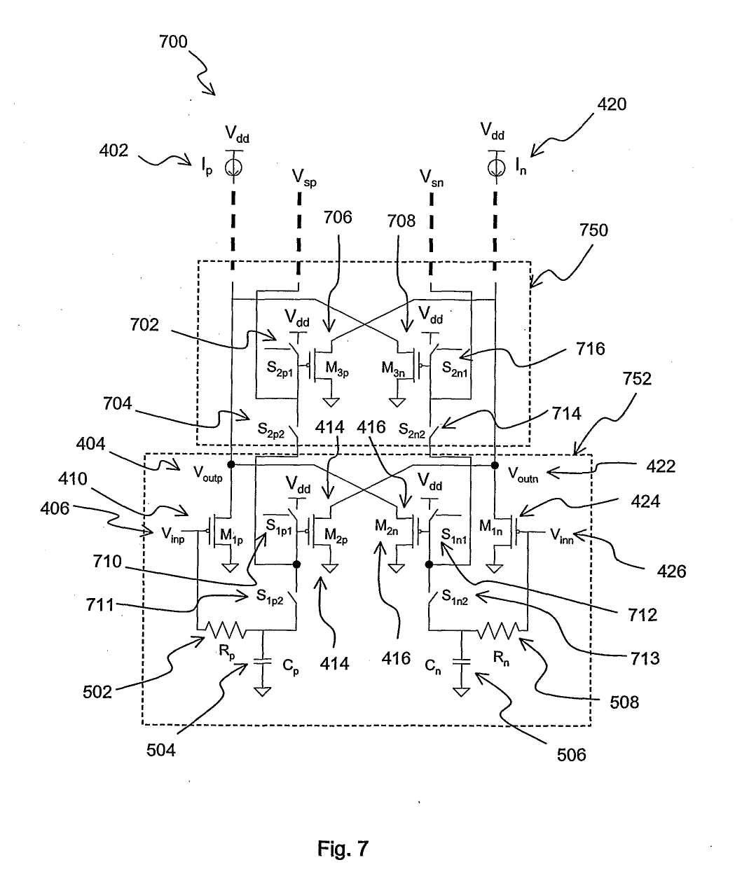

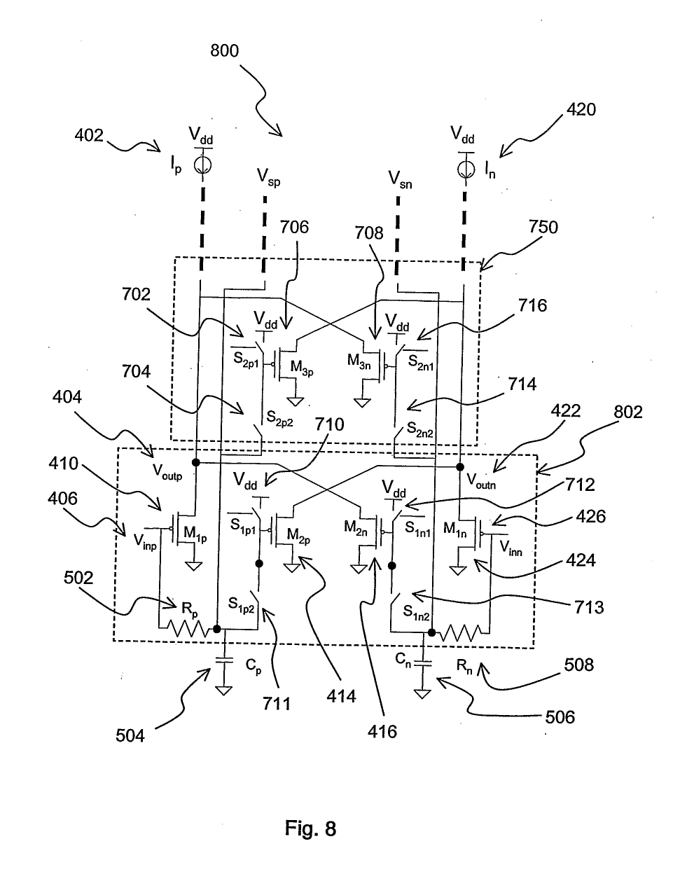

The degree of attenuation can be varied for the SFAs (500, 600) of FIGS. 5 and 6 by either analogue or digital techniques. According to an analogue technique, biasing voltage V_{bias} at the gates of M₂ₚ (414) and M₂ₙ (416) is varied to control the attenuation. In most modern attenuation control algorithm that employs digital control loops, a digital technique for attenuation control is preferred. In this case, two differential SFAs (700, 800) are proposed, as shown in FIGS. 7 and 8. Control switches (i.e., PMOS or NMOS configured) are used for attenuation control. The difference between these two attenuators (700, 800) is that control switches are either connected in series or parallel.

Referring to FIG. 7, a digitally switchable SFA (700) is illustrated. In FIG. 7, there are two stages of sub-circuits (750, 752) connected in a ladder form. The first stage of the ladder (750) is mainly formed by a pair of cross-coupled transistors (M₃ₚ, M₃ₙ) (706, 708) with complimentary switches (S₂ₚ₁, S₂ₚ₂, S₂ₙ₁, S₂ₙ₂) (702, 704, 716, 714) controlling their gates. At the positive current Iₚ (402) side, the source of M₃ₚ (706) is cross-coupled to the negative current input Iₙ (420). At the negative current Iₙ (420) side, the source of M₃ₙ (708) is connected to the positive current input Iₚ (402). Both drains of the M₃ₚ (706) and M₃ₙ (708) are connected to ground. There are two switches connected in series for each of transistors (706, 708). In particular, at the positive current side, the gate of M₃ₚ (706) is controlled by a pair of serially connected complimentary switches S₂ₚ₁ (702) and S₂ₚ₂ (704). At the negative current Iₙ (420) side, the gate of M₃ₙ (708) is also controlled by a pair of serially connected complimentary switches S₂ₙ₁ (716) and S₂ₙ₂ (714). In the first stage of the ladder (750), transistors M₃ₚ (706) and M₃ₙ (708) are used as control transistors.

The second stage of the ladder (752) has similar arrangement to the SFA (600) of FIG. 6. However, as an addition, a pair of serially complimentary connected switches is provided for the gates of the transistors (M₂ₚ, M₂ₙ) (414, 416) respectively. In particular, the gate of M₂ₚ (414) is controlled by a pair of serially connected complimentary switches S₁ₚ₁ (710) and S₁ₚ₂ (711). Symmetrically, at the negative current Iₙ (420) side, a pair of serially connected complimentary switches S₁ₙ₁ (712) and Sᵢₙ₂ (713) controls the gate of M₂ₙ (416). At the positive current Iₚ (402) side, the switches (710, 711) of the second stage (752) are serially connected to the switches (702, 704) of the first stage (750). At the negative current Iₙ (420) side, the switches (716, 714) of the first stage (750) are also connected serially to the switches (712, 713) of the second stage (752).

FIG. 8 shows an alternative SFA (800). The SFA (800) has two stages (750, 802). At the positive current Iₚ (402) side, switches of each control and input transistor are still connected in series but the pair of complimentary switches (702, 704) of the first stage (750) are connected to the pair of complimentary switches (710, 711) of the second stage (802) in parallel. Similarly, at the negative current Iₙ (420) side, the pair of complimentary switches (716, 714) of the first stage (750) is also connected to the pair of complimentary switches (712, 713) of the second stage (802) in parallel. This enables the first and the second stages (750, 802) of the SFA (800) to be independently switched on and off which offers different functionalities compared to the SFA (700) of FIG. 7.

The degree of attenuation of the differential SFAs (700, 800) is given by

$$G = \frac{{( W / L )}_{M 1 p}}{{( W / L )}_{M 1 p} + {{S}_{1} ( W / L )}_{M 2 n} + {{S}_{2} ( W / L )}_{M 3 n}} \qquad ( 4 )$$

Here, switches S₁ (S₁ₚ₁, S₁ₚ₂, S₁ₙ₁, S₁ₙ₂) and S₂ (S₂ₚ₁, S₂ₚ₂, S₂ₙ₁, S₂ₙ₂) have a binary number of either “1” or “0” for obtaining “on” and “off” states. In series switches implementation of FIG. 7, attenuation control of S₂ (S₂ₚ₁, S₂ₚ₂, S₂ₙ₁, S₂ₙ₂) (702, 704, 716, 714) depends on the on/off state of S₁ (S₁ₚ₁, S₁ₚ₂, S₁ₙ₁, S₁ₙ₂) (710, 711, 712, 713) respectively. In the parallel switches implementation of FIG. 8, attenuation controls of two stages (750, 802) are independent from each other. The purpose of including complementary switches (two serially connected switches for a transistor) in the circuits (700, 800) is to turn off the control transistors (706, 708, 414, 416) when they are not in attenuation control mode. Complimentary switches improve the attenuation control accuracy and prevent signal feed-through through a single switch since large incoming signal is expected for most attenuators. In FIGS. 7 and 8, S₂ₚ₁ (702) and S₂ₚ₂ (704) form a pair of complimentary switches of S₂ₚ; S₂ₙ₁ (716) and S₂ₙ₂ (714) form a pair of complimentary switches of S₂ₙ; S₁ₚ₁ (710) and S₁ₚ₂ (711) form a pair of complimentary switches of S₁ₚ; S₁ₙᵢ (712) and S₁ₙ₂ (713) form a pair of complimentary switches of S₁ₙ.

The proposed SFAs (700, 800) provide high linearity without consuming much power. They (700, 800) also provide wide bandwidth without consuming much power. The SFAs' (700, 800) gains can be set by an input transistor aspect ratio, which is highly accurate and independent from the variation of the power supply, process, and temperature. The SFAs (700, 800) operate at low voltage and can handle very large input signal. The SFAs (700, 800) can also be used with both DC/AC coupling. The SFAs (700, 800) both use source follower as gain attenuator and adopt low-pass filter for self-biasing. Degrees of attenuation control of these two SFAs (700, 800) can be varied by switches.

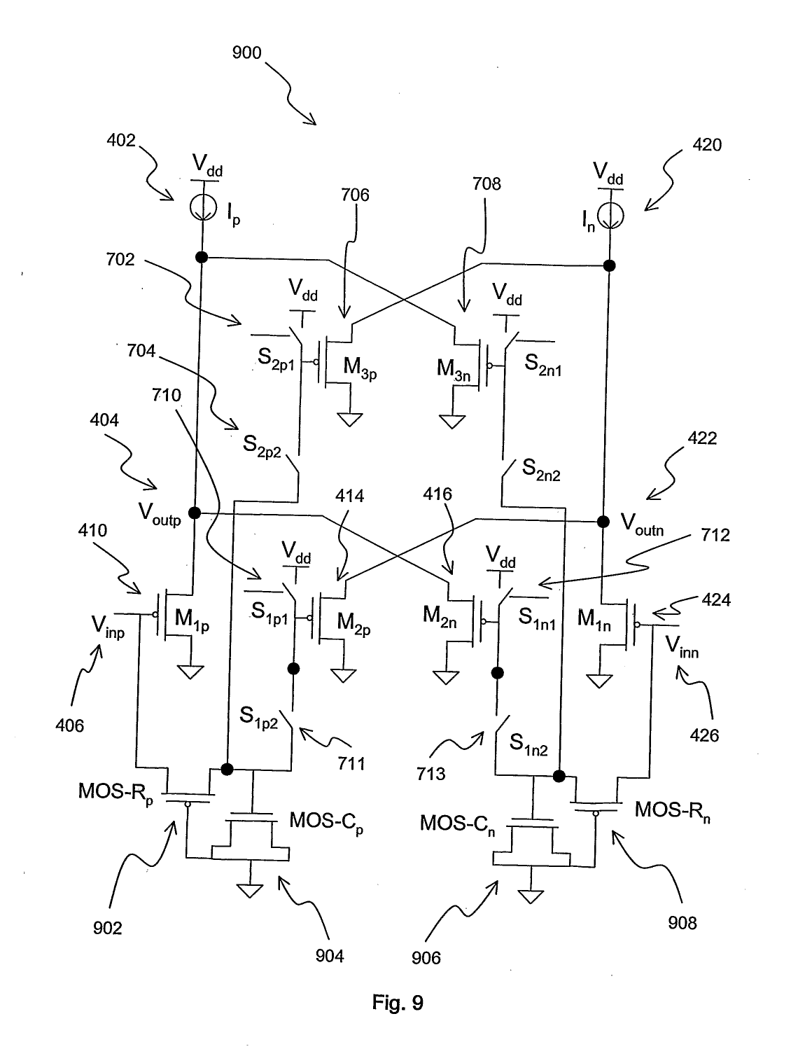

A practical implementation for the SFA (800) of FIG. 8 is given in FIG. 9. It is implemented using 0.18 μm CMOS. In the implemented circuit (900), resistors and capacitors of FIG. 8 are implemented by CMOS configured resistors (MOS-R) (902, 908) and capacitors (MOS-C) (904, 906). The aspect ratio of the input and control transistors is given in Table 1. The measured gain control of the SFA (900) with respect to the control switches is tabulated in Table 2.

TABLE 1
Input and control transistors aspect ratio

| | M₁ₚ, M₁ₙ | M₂ₚ, M₂ₙ | M₃ₚ, M₃ₙ |
|---|---|---|---|
| m(W/L) | 6(5.00/0.18) | 2(5.00/0.18) | 4(5.00/0.18) |

Note:
m: number of fingers;
W: channel width (μm);
L: channel length (μm)

TABLE 2
Measured SFA gain control

| | | |
|---|---|---|
| Gain (dB) | Linearity | Bandwidth |

| S₂ | S₁ | Calculated | Measured | (dBm) | (MHz) |
|---|---|---|---|---|---|
| 0 | 0 | −0.405 | −0.4 | 16.5 | 150 |
| 0 | 1 | −2.805 | −2.8 | 17.0 | 180 |
| 1 | 0 | −4.642 | −4.6 | 17.0 | 200 |
| 1 | 1 | −6.105 | −6.1 | 18.0 | 210 |

Referring to Table 1, the input and control transistors are constructed based on a unit transistor with unit aspect ratio of 5.00 μm/0.18 μm.

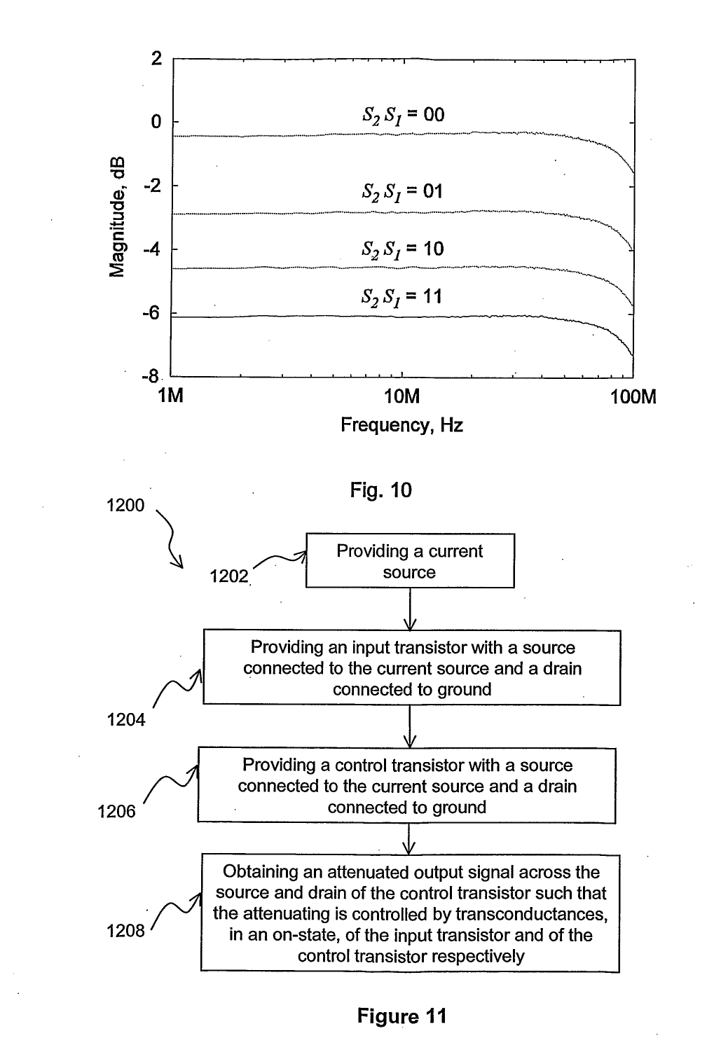

Referring also to Table 2, which presents summarised pass-band attenuation results, the measured gains of the attenuator (900) match well with the calculated gains. This indicates the expected performance of the proposed SFA (900). The linearity of the SFA (900) is also measured with two-tones in-band signals, which confirms high linearity of the SFA (900). The SFA (900) also achieves very high bandwidth of more than 150 MHz, which is based on driving 2 pF capacitors. Although the SFA (900) achieves high linearity and high bandwidth, it merely consumes 500 μA from 1.8V supply voltage, which includes biasing circuitries. It is worth mentioning that the SFA (900) only occupies very small area, which is only 120×60 μm². A test chip of the SFA (900) is packaged with SOIC-8 for testing. The magnitude responses of the SFA (900) controlled by the two bits switches (S₁, S₂) are shown in FIG. 10. The overall performance and characteristic of the SFA (900) are tabulated in Table 3. Based on these results, the SFA (900) is confirmed to be very suitable to be used as a low-power, low-voltage, low-cost, and wide band attenuator.

TABLE 3
SFA overall measured performance

| | | |
|---|---|---|
| Specification | 0.18 | μm CMOS |
| Supply Voltage | 1.8 | V |
| Drain Current | 500 | μA |
| Active Area | 120 × 60 | μm² |
| 3-dB bandwidth | 150 to 210 | MHz |
| IIP3 | >16 | dBm |
| Attenuation (2 bits, extendable) | 0 to −6 | dB |

Referring to FIG. 10, for the experimental results, different degrees of attenuation are plotted for various switches on/off states. In FIG. 10, the vertical axis represents voltage gain (2 to −8 dB) of the SFA (900) and the horizontal axis represents the frequency range (1 to 100 MHz) of the attenuation. The attenuation degree is plotted according to different switches on/off states. Here, “1” means the switch is turned on and “0” means the switch is turned off. Accordingly, “S₁S₂=00” means both switches are turned off where no attenuation occurs. When both switches are turned on (S₁S₂=11) (Here, S₁=S₁ₚ₁=S₁ₚ₂=S₁ₙ₁=S₁ₙ₂; S₂=S₂ₚ₁=S₂ₚ₂=S₂ₙ₁=S₂ₙ₂), the maximum attenuation occurs. The simulation result of FIG. 10 shows that this circuit (900) gives linear and stable attenuation over a large range of frequency about 1 to 50 MHz in a stable and efficient manner.

It will be appreciated by a person skilled in the art that, where a differential SFA is not required, alternative embodiments can provide a single current source SFA based on either the positive or negative current sides of the SFAs (400, 500, 600, 700, 800 and 900). In such embodiments, instead of the cross-coupling connections to avoid DC offset in the SFAs (600, 700, 800, and 900), the sources of the control transistors, i.e. M₃ₚ (706) and M₂ₚ (414) in FIGS. 7 and 8, are connected to the same (positive) current source (402) as the source of the input transistor (410).

In the above-mentioned embodiments, NMOS transistors may replace PMOS transistors where appropriate.

FIG. 11 shows a flowchart 1200 illustrating a method for attenuating a signal according to an example embodiment. At step 1202, a current source is provided. At step 1204, an input transistor with a source connected to the current source and a drain connected to ground is provided. At step 1206, a control transistor with a source connected to the current source and a drain connected to ground is provided. At step 1208, an attenuated output signal is provided across the source and drain of the control transistor such that the attenuating is controlled by transconductances, in an on-state, of the input transistor and of the control transistor respectively.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A source follower attenuator circuit comprising:
a current source;
an input transistor with a source connected to the current source and a drain connected to ground;
a control transistor with a source connected to the current source and a drain connected to ground;
wherein an attenuated output signal across the source and drain of the control transistor is controlled by transconductances, in an on-state, of the input transistor and of the control transistor respectively.

2. The attenuator circuit as claimed in claim 1, further comprising a RC low-pass filter circuit connected between the gate of the input transistor and the gate of the control transistor for self-biasing the control transistor from an input voltage provided at the gate of the input transistor.

3. The attenuator circuit as claimed in claim 2, wherein the RC low-pass filter circuit comprises MOS components.

4. The attenuator circuit as claimed in claim 1, further comprising a plurality of control transistors, each control transistor with a source connected to the current source and a drain connected to ground and with gates of the respective control transistors are connected in series to a biasing voltage, wherein the attenuated output signal across the source and drain of one of the control transistors is controlled by transconductances, in an on-state, of the input transistor and all of the plurality of control transistors respectively.

5. The attenuator circuit as claimed in claim 1, further comprising a plurality of control transistors, each control transistor with a source connected to the current source and a drain connected to ground and with gates of the respective control transistors are connected in parallel to a biasing voltage, wherein the attenuated output signal across the source and drain of one of the control transistors is variably controlled by the transconductance, in an on-state, of the input transistor and by transconductances of those of the plurality of control transistors which are in an on state respectively.

6. The attenuator circuit as claimed in claim 5, further comprising switches for controlling the on state of the respective control transistors.

7. The attenuator circuit as claimed in claim 6, wherein each of the switches comprises two switch elements for preventing signals from feeding through the switches.

8. A differential source follower attenuator comprising:
a first and a second attenuator circuits as claimed in claim 1;
wherein the current source of the first attenuator circuit comprises a positive current source, and the current source of the second attenuator circuit comprises a negative current source.

9. The differential source follower attenuator according to claim 8, wherein the source of each control transistor of the first attenuator circuit is connected to the negative current source of the second attenuator circuit, and the source of each control transistor of the second attenuator circuit is connected to the positive current source of the first attenuator circuit, for DC offset through cross-coupling of the first and second attenuator circuits.

10. A method for attenuating a signal comprising:
providing a current source;
providing an input transistor with a source connected to the current source and a drain connected to ground;
providing a control transistor with a source connected to the current source and a drain connected to ground;
obtaining an attenuated output signal across the source and drain of the control transistor such that the attenuating is controlled by transconductances, in an on-state, of the input transistor and of the control transistor respectively.

11. The attenuator circuit as claimed in claim 2, further comprising a plurality of control transistors, each control transistor with a source connected to the current source and a drain connected to ground and with gates of the respective control transistors are connected in series to a biasing voltage, wherein the attenuated output signal across the source and drain of one of the control transistors is controlled by transconductances, in an on-state, of the input transistor and all of the plurality of control transistors respectively.

12. The attenuator circuit as claimed in claim 3, further comprising a plurality of control transistors, each control transistor with a source connected to the current source and a drain connected to ground and with gates of the respective control transistors are connected in series to a biasing voltage, wherein the attenuated output signal across the source and drain of one of the control transistors is controlled by transconductances, in an on-state, of the input transistor and all of the plurality of control transistors respectively.

13. The attenuator circuit as claimed in claim 2, further comprising a plurality of control transistors, each control transistor with a source connected to the current source and a drain connected to ground and with gates of the respective control transistors are connected in parallel to a biasing voltage, wherein the attenuated output signal across the source and drain of one of the control transistors is variably controlled by the transconductance, in an on-state, of the input transistor and by transconductances of those of the plurality of control transistors which are in an on state respectively.

14. The attenuator circuit as claimed in claim 3, further comprising a plurality of control transistors, each control transistor with a source connected to the current source and a drain connected to ground and with gates of the respective control transistors are connected in parallel to a biasing voltage, wherein the attenuated output signal across the source and drain of one of the control transistors is variably controlled by the transconductance, in an on-state, of the input transistor and by transconductances of those of the plurality of control transistors which are in an on state respectively.

15. The attenuator circuit as claimed in claim 4, further comprising switches for controlling the on state of the respective control transistors.
